(19) United States
(12) Patent Application Publication
(10) Pub. No.: US 2012/0018884 A1
(43) Pub. Date: Jan. 26, 2012

(54) Semiconductor package structure and forming method thereof

(75) Inventors: Yu-Yu Lin, Hsinchu City (TW); Li-Hua Lin, Hsinchu City (TW); Chung-Kai Wang, Hsinchu City (TW)

(73) Assignee: Global Unichip Corporation, Hsinchu City (TW)

(21) Appl. No.: 12/923,461

(22) Filed: Sep. 23, 2010

(30) Foreign Application Priority Data
Jul. 23, 2010 (TW) 099124265

(51) Int. Cl. H01L 23/48; H01L 21/56

(52) U.S. Cl. 257/738; 438/127; 257/E23.021; 257/E21.502

(57) ABSTRACT

The present invention provides a semiconductor package structure, which includes a substrate having a top surface and a back surface, a plurality of first connecting points on the top surface and a plurality of second connecting points on the back surface; a chip having an active surface and back surface, a plurality of pads on the active surface, and the chip is attached on the top surface of the substrate; a plurality of wires is electrically connected the plurality of pads on the active surface of the chip with the plurality of first connecting points on the top surface of substrate; a first encapsulant is filled to cover portion of the plurality of wires, the chip, and the portion of top surface of the substrate; a second encapsulate is filled to cover the first encapsulant, the plurality of wires and is formed on portion of the top surface of the substrate, in which the Yang's module of the second encapsulant is different with that of the first encapsulant; and a plurality of connecting components is disposed on the back surface of the substrate and is electrically connected the plurality of second connecting points.

### BACKGROUND OF THE INVENTION

1. Field of the Invention

The present invention related to a semiconductor device, and more particularly to a semiconductor package structure to reduce the stress on the chip.

2. Description of the Prior Art

Integrated circuits (IC) are typically housed within a package that is mounted to a printed circuit board (PCB). The package has conductive leads or pins that are soldered to the PCB and coupled to the IC by a lead frame. One kind of package commonly referred to as a ball grid array (BGA) is an integrated circuit package which has a plurality of solder balls that interconnect the package to a PCB. The solder balls are attached to a polyimide based flexible circuit board which has a number of conductive traces and accompanying solder pads. The integrated circuit die is connected to the solder pads of the flexible circuit by wire bonds and electrically coupled to the solder balls through conductive traces routed across the flexible circuit.

FIG. 1 illustrates a conventional BGA package 100 that includes a substrate 105 having a chip 115 (i.e., an IC chip) attached to the substrate 105 via die attach adhesive 110 thereon. The substrate 105 contains embedded multiple horizontal layers of metal conductors (not shown) connected by vertical conductors (not shown). Chip 115 is positioned over substrate 105. Inputs/outputs (I/Os) of chip 115 are connected are attached to a bottom surface of substrate 105 and function as the I/O pins of BGA package 100. A top surface of BGA package 100 is encapsulated or over-molded by epoxy molding (e.g., resin-based) compound 140, for example, by a transfer molding process. In its final form, package 100 is soldered to PCB (not shown). A plurality of connecting components 130 is disposed on the back surface (not shown) of the substrate 105.

The plurality of metal wires 120 and 122 would be deformed or swept due to the higher attacking velocity of the molding material during the molding process, so that the circuit short would be generated between the die and substrate, and the reliability would be reduced.

In addition, the volume of the molding material would be shrunk after injection molding process. The CTE (coefficient of thermal expansion) is mismatched between the 2.6 ppm/°C. for the die (or IC chip) and alpha 1 is about 10 ppm/°C. and alpha 2 is about 50 ppm/°C. for the molding material, such that the chip would be sustained the stress to introduce the breakdown to diminish the reliability of the package structure. Moreover, the molding material with large heat dissipating coefficient for the application of the high power is common increasingly. Generally, the heat dissipating coefficient of the molding material can be increased by increasing the proportion of the silica or other metals within the molding material, but the mobility of molding material would be diminished, so that the plurality of wires 120 and 122 could be extruded to cause the deformation or cause the circuit short during the molding process.

### SUMMARY OF THE INVENTION

According to above problems, the primary objective of the present invention is to provide a semiconductor package structure, such that the deformation or sweep of the plurality of wires can be prevented when the molding material with the higher fluid velocity during the molding process.

Another primary objective of the present invention is to provide a semiconductor package structure having two encapsulants with two different Yang's modules to prevent the volume of the encapsulant is to be shrunk, and the mismatch of CTE between the encapsulant and the chip also can be prevented, such that the breakdown of the chip can be eliminated.

According to above objectives, the present invention provides a semiconductor package structure, which includes a substrate having top surface and back surface, a plurality of first connecting points on the top surface and a plurality of second connecting points on the back surface; a chip having an active surface and back surface, a plurality of pads on the active surface, and the chip is attached on the top surface of the substrate; a plurality of wires is electrically connected the plurality of pads on the active surface of the chip with the plurality of first connecting points on the top surface of substrate; a first encapsulant is filled to cover portion of the plurality of wires, the chip, and the portion of top surface of the substrate; a second encapsulate is filled to cover the first encapsulant, the plurality of wires and is formed on portion of the top surface of the substrate, in which the Yang's module of the second encapsulant is different with that of the first encapsulant; and a plurality of connecting components is disposed on the back surface of the substrate and is electrically connected the plurality of second connecting points.

In addition, according to above semiconductor package structure, the present invention provides a method for fabricating the semiconductor package structure, which includes: providing a substrate having a top surface and a back surface, a plurality of first connecting points on the top surface and a plurality of second connecting points on the back surface; providing at least one chip having an active surface and a back surface, and a plurality of pads on the active surface; attaching the chip on the top surface of the substrate; forming a plurality of wires to electrically connect the plurality of pads on the active surface of the chip with the plurality of first connecting points on the top surface of the substrate; forming a first encapsulant to cover portion of the plurality of wires, chip, and form on portion of top surface of the substrate; forming a second encapsulant to cover the plurality of wires, the first encapsulant, and on the top surface of the substrate, in which the Yang's module of the first encapsulant is different with that of the second encapsulant; and forming a plurality of connecting components on the back surface of the substrate and is electrically connected the plurality of second connecting points.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows a cross-sectional view of the warpage of a conventional semiconductor package structure according to the conventional prior art;

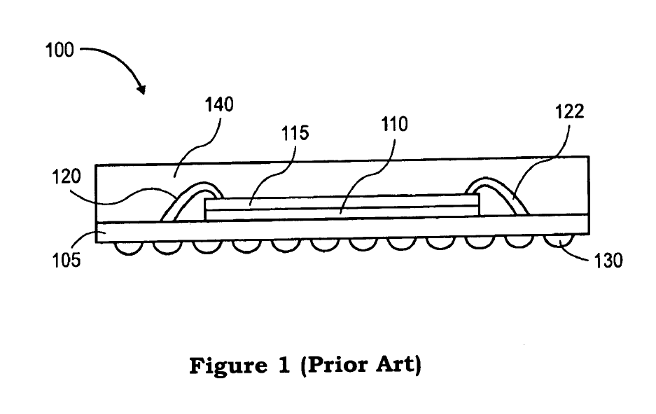

FIG. 2 shows a cross-sectional view of the substrate having a chip thereon according to the present invention disclosed herein;

FIG. 3 shows a cross-sectional view of the plurality of wires that is electrically connected the active surface on the chip with the top surface of the substrate according to the present invention disclosed herein;

FIG. 4 shows a cross-sectional view of the first encapsulant that is covered the structure of FIG. 3 according to the present invention disclosed herein; and

FIG. 5 shows a cross-sectional view of the molding process is performed to form a semiconductor package structure according to the present invention disclosed herein.

### DESCRIPTION OF THE PREFERRED EMBODIMENT

The present invention will now be described more fully hereinafter with reference to the accompanying drawings, in which preferred embodiments are shown. The objective of the present invention is to provide a method for fabricating semiconductor package device. In the following, the well-known knowledge regarding the of the invention such as the formation of chip and the process for forming package structure would not be described in detail to prevent from arising unnecessary interpretations. However, this invention will be embodied in many different forms and should not be construed as limited to the embodiments set forth herein.

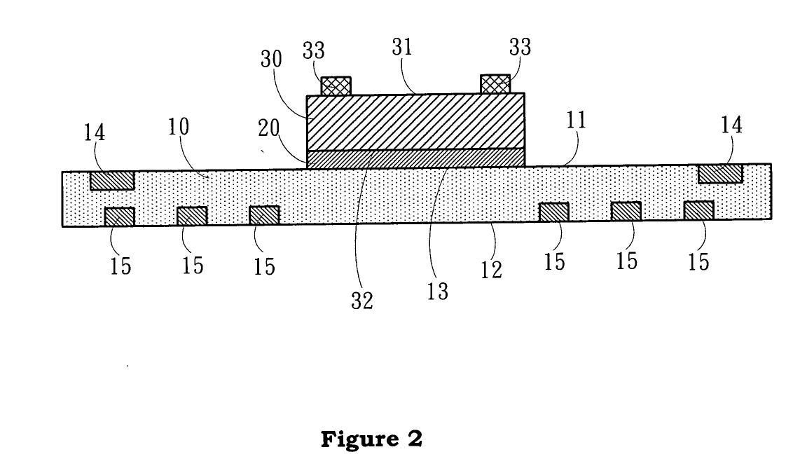

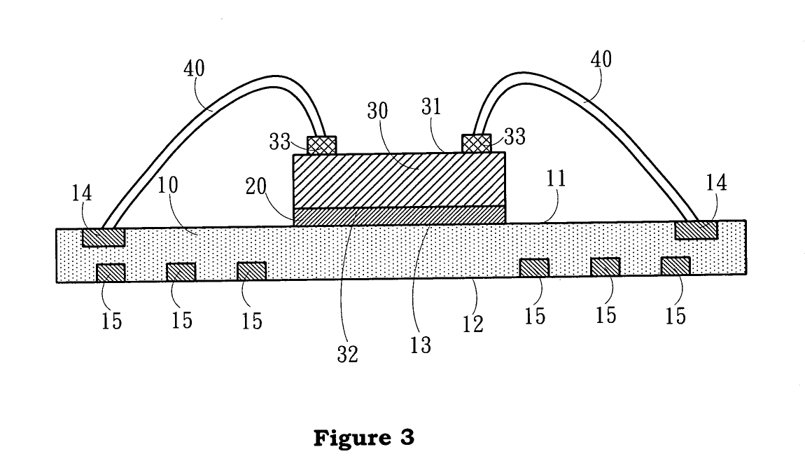

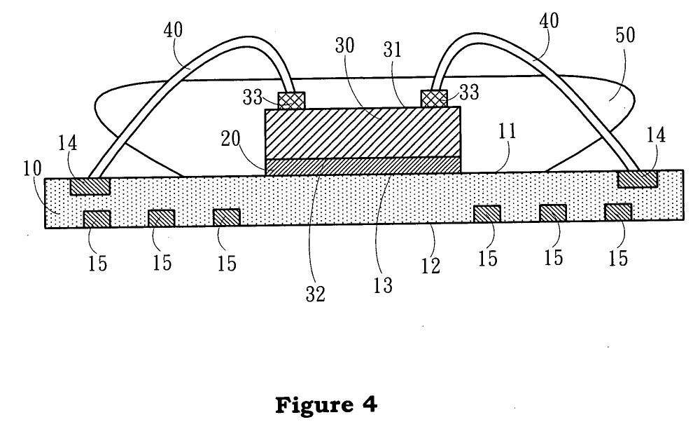

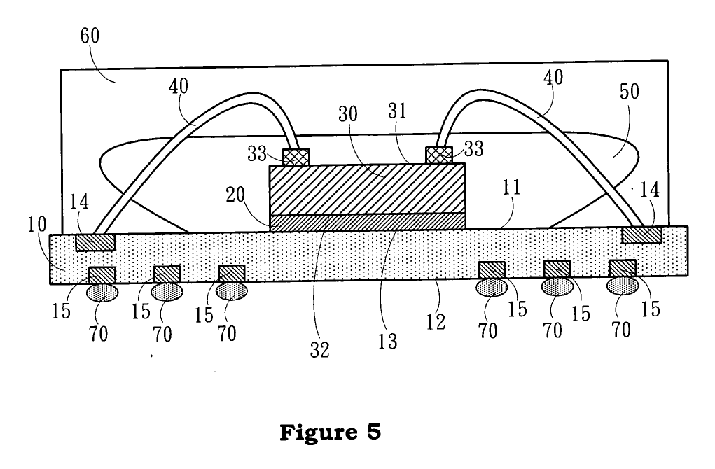

From FIG. 2, FIG. 3, FIG. 4 to FIG. 5 are shown as the flow chart for fabricating the semiconductor package device of the invention. FIG. 2 shows a view of a substrate having a chip thereon according to present invention. In FIG. 2, substrate 10 is provided with top surface 11 and back surface 12, chip place area 13 is disposed on top surface 11 of substrate 10, and a plurality of first connecting points 14 is disposed on top surface 11 near chip place area 13 on substrate 10, and a plurality of second connecting points 15 is disposed on back surface 12 of substrate 10. Then, the back surface 32 of chip 30 is attached on chip place area 13 on substrate 10. In the embodiment, an adhesive layer 20 is further disposed between chip 30 and chip place area 13 of substrate 10 to fix chip 30 on chip place area 13 on substrate 10 tightly, and a plurality of pads 33 is disposed on active surface 31 of chip 30.

Please referring to FIG. 3, shows the plurality of wires that is formed on the active surface of the chip and is electrically connected the substrate. In FIG. 3, one end (not shown) of the plurality of wires 40 is formed on the plurality of pads 33 on active surface 31 of chip 30 by wire bonding process or reverse wire bonding process. In addition, another end of the plurality of wires 40 is formed on the plurality of first connecting points 14 near chip place area 13 on the top surface 11 of substrate 10, such that chip 30 is electrically connected substrate 10 through the plurality of wires 40.

According to the conventional prior art, the mobility of the molding material with higher velocity will attack the plurality of wires 40 to introduce the deformation or sweep of the plurality of wires 40 during the molding process. Thus, the short circuit would be generated between chip 30 and substrate 10, and reliability of the package structure would be reduced. Moreover, the volume of molding material is to be shrunk after injection molding process. The CTE (coefficient of thermal expansion) is mismatched between the 2.6 ppm/°C. for the die (or IC chip) and alpha 1 is about 10 ppm/°C. and alpha 2 is about 50 ppm/°C. for the molding material. In order to prevent the breakdown from chip 10 that is sustained by the stress to reduce the reliability of the package structure, a first molding process is provided with a first encapsulant 50 to cover portion of the plurality of wires 40, chip 30, and the portion of top surface 11 of substrate 10, as shown in FIG. 4. In this embodiment, the first encapsulant 50 with high CTE and lower Yang's module, the material of first encapsulant 50 is silicone gel and the CTE is about 320 ppm/°C. or polyimide with CTE is about 28 ppm/°C. Therefore, the purpose of forming first encapsulant 50 is used to fix the plurality of wires 40 between chip 30 and substrate 10, such that the sweep of the plurality of wires 40 can be prevented in follow-up molding process.

Thereafter, referring to FIG. 5, shows another molding process that is performed to the structure of FIG. 4 to form a package structure. In FIG. 5, a second molding process is provided with a second encapsulant 60 such as EMC (epoxy molding compound) to cover portion of first encapsulant 50, the plurality of wires 40 and top surface 11 of substrate 10 to form a package structure after portion of the plurality of wires 40 and chip 30 is encapsulated by first encapsulant 50. Because chip 30 is firstly encapsulated by first encapsulant 50, and chip 30 would not be broken to maintain the reliability of the package structure due to the mismatch of CTE between chip 30 and the second encapsulant 60 during second encapsulant 60 is cured to form a package structure, and the temperature of the package structure can be decreased till the same as the room temperature.

Next, also referring to FIG. 5, a plurality of connecting components 70 is formed on back surface 11 of substrate 10 and is electrically connected the plurality of second connecting points 15 on back surface 11 of substrate 10 to complete the semiconductor package structure. In this embodiment, the material of the plurality of connecting components 70 is solder ball which is used to electrically connect the exterior electronic device (not shown).

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A semiconductor package structure, comprising:
a substrate having a top surface and a back surface, a plurality of first connecting points on said top surface and a plurality of second connecting points on said back surface;
a chip having an active surface and a back surface, said active surface of said chip being turned upward and said back surface being attached on said top surface of said substrate, and a plurality of pads on said active surface;
a plurality of wires being electrically connected said plurality of pads on said active surface of chip with said plurality of first connecting points on said top surface of said substrate;
a first encapsulant covering portion of said plurality of wires, said chip and a portion of said top surface of said substrate;
a second encapsulant for covering said first encapsulant and said plurality of wires, and being formed on said portion of said top surface of said substrate, wherein the Young's Modulus of said first encapsulant being different with that of said second encapsulant; and
a plurality of connecting components being disposed on said back surface of said substrate and being electrically connected said plurality of second connecting points.

2. The semiconductor package structure according to claim 1, further comprising an adhesive layer is disposed between said back surface of said chip and said top surface of said substrate.

3. The semiconductor package structure according to claim 1, wherein the material of said first encapsulant is selected from the group consisting of: silicone gel and polyimide.

4. The semiconductor package structure according to claim 1, wherein material of said second encapsulant comprises epoxy molding compound.

5. The semiconductor package structure according to claim 1, wherein said plurality of connecting components comprises solder ball.

6. A method for fabricating semiconductor package structure, comprising:
providing a substrate having a top surface and a back surface, a plurality of first connecting points on said top surface of said substrate, and a plurality of second connecting points on said back surface of said substrate;
providing at least one chip having an active surface and a back surface, and a plurality of pads on said active surface;
forming a plurality of wires to electrically connect said plurality of pads on said active surface of said chip with said plurality of first connecting points on said top surface of said substrate;
forming a first encapsulant to cover portion of said plurality of wires, said chip and on said portion of said top surface of said substrate;
forming a second encapsulant to cover portion of said plurality of wires, said first encapsulant and on said top surface of said substrate, wherein the Yang's modules of said second encapsulant being different with that of said second encapsulant; and
forming a plurality of connecting components on said back surface of said substrate and being electrically connected said plurality of second connecting points.

7. The method according to claim 6, further comprising an adhesive layer is formed between said back surface of said chip and said top surface of said substrate.

8. The method according to claim 6, wherein the method of forming said plurality of wires comprises wire bonding process.

9. The method according to claim 6, wherein the method of forming said plurality of wires comprises reverse wire bonding process.

10. The method according to claim 6, wherein the material of said first encapsulant is selected from the group consisting of silicone gel and polyimide.

11. The method according to claim 6, wherein material of said second encapsulant comprises epoxy molding compound.

12. The method according to claim 6, wherein said plurality of connecting components comprises solder ball.
